(19) United States
(12) Patent Application Publication
(10) Pub. No.: US 2014/0014900 A1
(43) Pub. Date: Jan. 16, 2014

(54) LIGHT EMITTING SOURCE AND METHOD FOR EMITTING LIGHT BASED ON BORON NITRIDE NANOTUBES

(71) Applicants: Angel Rubio Secades, Leioa (Vizcaya) (ES); Claudia Attaccalite, Leioa (Vizcaya) (ES); Ludger Wirtz, Leioa (Vizcaya) (ES)

(72) Inventors: Angel Rubio Secades, Leioa (Vizcaya) (ES); Claudia Attaccalite, Leioa (Vizcaya) (ES); Ludger Wirtz, Leioa (Vizcaya) (ES)

(73) Assignee: UNIVERSIDAD DEL PAIS VASCO-EUSKAL HERRIKO UNIBERTSITATEA, Leioa (Vizcaya) (ES)

(21) Appl. No.: 13/985,054

(22) PCT Filed: Feb. 22, 2012
(86) PCT No.: PCT/ES2012/070098

§ 371 Date: Sep. 13, 2013

(30) Foreign Application Priority Data
Feb. 22, 2011 (ES) P201130228

(51) Int. Cl. H01L 33/00

(52) U.S. Cl. CPC H01L 33/0041
USPC 257/13

(57) ABSTRACT

The present invention relates to a source for emitting broad spectrum light of controllable frequency comprising boron nitride nanotubes with defects caused by the vacancy of a boron atom in the tubular structure and wherein the source is further provided with means for producing an electric field perpendicular to the tube. The invention can be used as a field-effect transistor (by adding electrodes) or as a source for converting energy of an incoming beam.

### FIELD OF THE INVENTION

The present invention relates to a new light emitting source and a method for controlled light emission which allows varying the emission frequency, from infrared to far ultraviolet, as a result of applying small external fields and potentials.

### BACKGROUND OF THE INVENTION

Most solid devices used today as light emitters usually work in a single frequency and use non-linear optical techniques for duplicating, tripling, etc. said frequency. The spectrum be it visible, infrared or another spectral area is thus discretely swept. Light in a broad range of energies can continuously be obtained in large light installations such as synchrotron. A light source which in addition to emitting in a broad spectrum is safe, efficient and portable is required for normal applications in industrial laboratories and in the development of new optoelectronic devices as applications in communications, computing, data storage, etc.

Catholuminescence experiments have proven the great efficiency of light emission in the far ultraviolet (˜5.7-5.9 eV) of the hexagonal boron nitride (Watanabe, K. et to the, Nat. Mat. 3, 404 (2004)). These materials are characterised by their high thermal conductivity, toughness and elasticity, high resistance to etching and to damage caused by irradiation with particles. These boron nitride properties are very superior to those of other metals and semiconductors used today as light emitters, for example in applications linked to optical storage (DVD) or communications. However, the emission of these nanotubes is in a limited frequency, therefore they cannot be used in applications in which, as mentioned above, the emission needs to occur in a broader range of frequencies and in a controlled manner.

### OBJECT OF THE INVENTION

The object of the invention is to mitigate the technical problems mentioned in the above section. To that end, it proposes a source for emitting broad spectrum light of controllable frequency comprising boron nitride nanotubes with defects caused by the vacancy of a B atom in the tubular structure and where the source is further provided with means for producing an electric field perpendicular to the tube. In the context of this description, vacancy will be understood as the absence of a boron atom or its substitution with, for example, a carbon atom. The emitting source preferably comprises a support on top of which nanotubes are provided and an insulator and metal layer placed under said support, such that the insulator and the layer can receive an electric current and act as a capacitor, producing the perpendicular field. The insulator can be a silicon oxide substrate and the metal layer can be of doped silicon. The invention can be used as a field-effect transistor when two electrodes are incorporated thereto on each side of the support.

### BRIEF DESCRIPTION OF THE DRAWINGS

For the purpose of aiding to better understand the features of the invention according to a preferred practical embodiment thereof, a set of drawings is attached to the following description in which the following has been depicted with an illustrative character:

FIG. 1 is an operation diagram of the proposed device.

FIG. 2 is a graph depicting the development of the electronic gap depending on the electric applied field for tubes of different dimensions.

FIG. 3 shows the lattice of boron nitride and defects in said lattice.

FIG. 4 is a graph in which how the emission frequency can be controlled with small variations of the electric field can be seen.

FIG. 5 shows the dependency of the emission with the position of the defect in the nanotube for an electric field applied perpendicular to said nanotube.

FIG. 6 shows a FET incorporating the invention

FIG. 7 shows a converter device for converting the energy of applied photons incorporated by the invention.

### DETAILED DESCRIPTION OF THE INVENTION

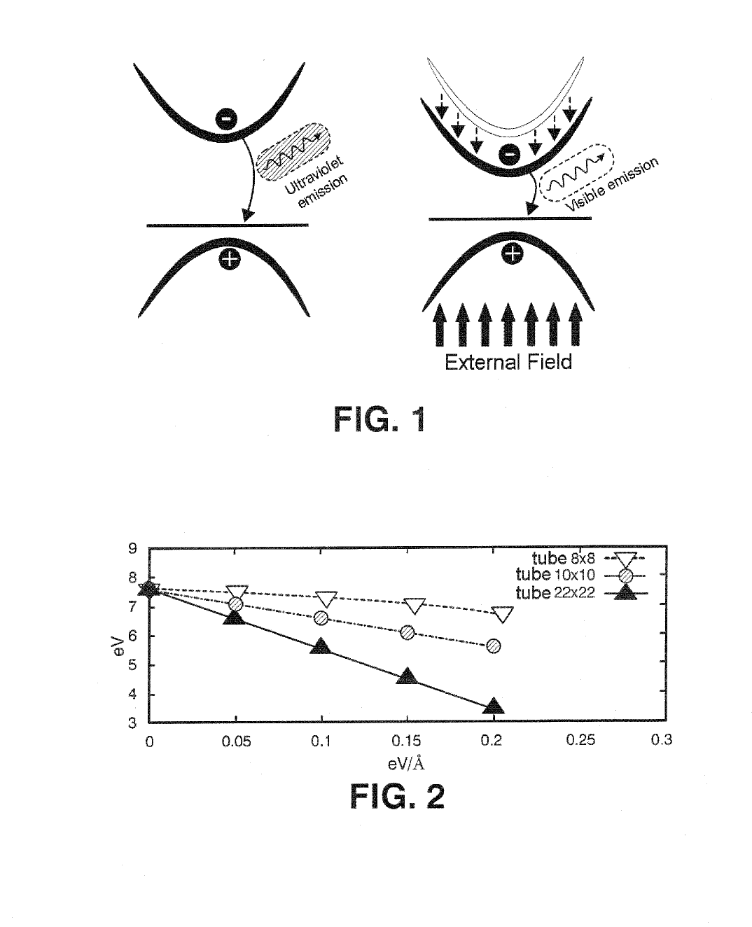

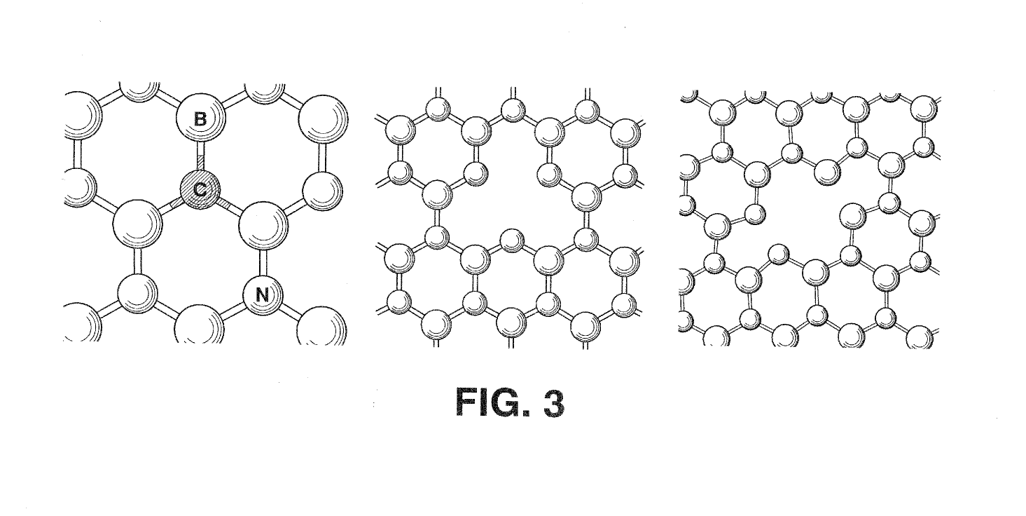

The operation of the new emitting source of the invention is based on the use of natural or induced defects of boron nitride nanotubes for controlling, by means of applying an electric field perpendicular to the tube, the colour of the emitted light (FIG. 1). This ease of control is only present in nanotubes given their cylindrical geometry and is absent in BN macroscopic structures (be they flat or three dimensional).

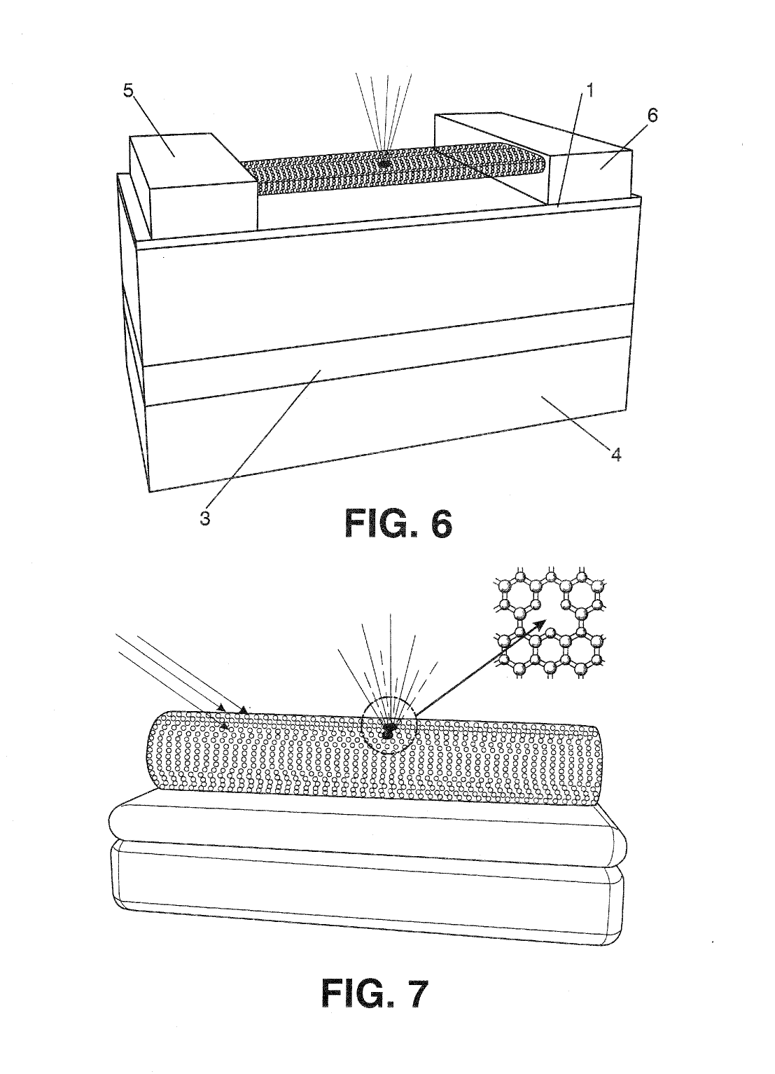

The generic configuration of the device (FIG. 6) comprises BN nanotubes (1) deposited on an insulating surface (3) (for example silicon oxide) acting as a dielectric to enable applying the control electric field through a conductor (4) (usually doped silicon).

The light emission is controllable in the entire the spectrum, ranging from infrared to far ultraviolet, in the device of the present invention. In particular, the defects which enable the controlled emission are those holes made on the wall of the nanotube due to the lack of a boron atom (FIG. 2).

Two ways of carrying out the invention are proposed:
i) as FET (“field-effect transistor”) a normal and bipolar transistor (FIG. 6). The manufacturing of a device with these characteristics would begin with the deposition of the nanotubes with defects on an insulating surface then lithographic contacts (5, 6) would be provided for making two opposite electrodes and lastly positive charges (holes) would be injected through an electrode and electrons would be injected through the other. Light emission will be produced when the electrons and holes meet in the defects and it is controlled by means of the perpendicular electric field. This particular example of carrying out the invention will be applied to integrated optoelectronic devices like information communication elements in computers or mobile telephony devices, solid state lasers, LEDS (variable range).
ii) as converter for converting the energy of the photons and/or electrons impacting the device as light with a wavelength determined by the potential applied to the BN nanotube (FIG. 7).

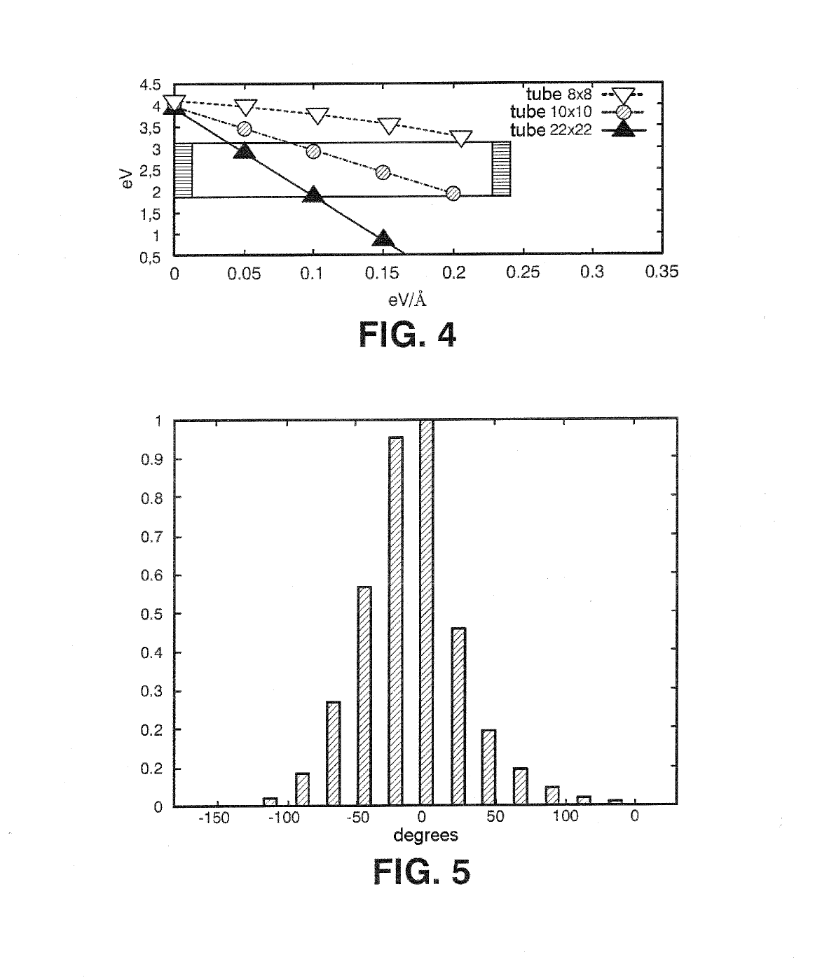

For an insulating material such as BN to act as an efficient and controlled light emitting source some electronic levels must be introduced in the forbidden band from which the light is emitted to the outside. These levels are activated by means of injecting electrons/holes in application i) and the irradiation with light for use in ii). The emission can be controlled with an external potential, the greater the energy difference between the induced level and the driving band of the insulator is, the greater the external potential is. For the case of BN, potentials of a few volts serve to control light emission (FIG. 4).

The new device does not need any type of atomic doping nor does it require complex growth on special substrates. The optimum boron nitride nanotube structure (tubular structures with lengths of the order of micrometers and diameters of the order of nanometre) naturally has electronic states in the forbidden band (linked to the B atom vacancies, which is also the more common defect). The position of these levels can be controlled upon adding the external electric field effect, (see FIG. 2 where the change of the gap depending on the electric field applied for a tube is shown).

The defects (boron vacancy or its absence and substitution with a carbon atom, for example) are directly responsible for the presence of electronic states located inside the forbidden band of the boron nitride very close to the lower driving band limit (a few eV decimals below and close to the Fermi level). When an external electric field perpendicular to the tube is applied, its relative position to the driving band limit moves at the same time as the latter moves for closing the gap (despite the fact that the intrinsic exciton resulting in absorption hardly modifies its energy). The process is based on the different character of the defect state wave functions and the nanotube valency and driving states with and without an applied electric field. The probability of light emission therefore depends on the position of the defect with respect to the applied electric field being maximum when they are parallel (FIG. 5)

The variation of the gap is linear with the applied field and with the frequency of the emitted light, without affecting the efficiency.

The emission occurs at room temperature, which is very beneficial for many applications.

In terms of manufacturing the device, the boron nitride nanotubes can be synthesised by means of standard scientific community methods for producing inorganic nanotubes (see for example P. Ayala, R. Arenal, A. Loisea, A. Rubio and T. Pichler, Reviews of Modern Physics 82, 1843-1885 (2010) for details on the different synthesis processes). These techniques allow synthesising both single-layer and multi-layer boron nitride nanotubes. The nanotubes thus synthesised have diameters of a few nanometres and are those which will be used for being integrated in the device of the invention. The structures thus synthesised have natural defects, more defects can be introduced by means of irradiation for improving the efficiency and the number of light emitting centres. This post-synthesis process is simple.

The electrical connections (2) can be made by means of lithographic techniques and standard electro-deposition.

The new device is easily integrated into current microelectronics technology (e.g. field-effect transistors) and finds applications in data storage and reading, communications and components for optical computing and biomedical treatments, among others.

1.-5. (canceled)

6. Source for emitting broad spectrum light of controllable frequency comprising boron nitride nanotubes wherein the boron nitride nanotubes comprise defects caused by the vacancy of a boron atom in the tubular structure and defects introduced by means of irradiation, and wherein the source is further provided with means for producing an electric field perpendicular to the tube.

7. Source for emitting light according to claim 6, further comprising a support where the nanotubes are placed and an insulator and metal layer under said support, such that the insulator and the layer can receive an electric current and act as a capacitor, producing the perpendicular field.

8. Source for emitting light according to claim 7, wherein the insulator is a silicon oxide substrate.

9. Source for emitting light according to claim 6, wherein the metal layer is of doped silicon.

10. Field-effect transistor comprising the source of claim 7 and two electrodes on each side of the support.

11. Source for emitting light according to claim 7, wherein the metal layer is of doped silicon.

12. Field-effect transistor comprising the source of claim 8 and two electrodes on each side of the support.

10. Field-effect transistor comprising the source of claim 9 and two electrodes on each side of the support.
